(19) United States
(12) Patent Application Publication
(10) Pub. No.: US 2006/0260750 A1
(43) Pub. Date: Nov. 23, 2006

(54) Plasma processing apparatuses and methods

(76) Inventor: Neal R. Rueger, Boise, ID (US)

Correspondence Address: WELLS ST. JOHN P.S., 601 W. FIRST AVENUE, SUITE 1300, SPOKANE, WA, 99201, US

(21) Appl. No.: 11/492,500

(22) Filed: Jul. 24, 2006

Related U.S. Application Data
(63) Continuation of application No. 10/930,993, filed on Aug. 30, 2004.

(51) Int. Cl. C23F 1/00; H01L 21/20; H01L 21/302; C23C 16/00; H01L 21/31

(52) U.S. Cl. 156/345.38; 156/345.35; 118/723 R

(57) ABSTRACT

A plasma processing apparatus and method includes a processing chamber having a substrate support and at least two separate and independently controlled devices selected from the following three devices: a first plasma generator, a second plasma generator, and an electron source. The first plasma generator directs plasma-generated cations toward the substrate support. The second plasma generator directs plasma-generated reactive neutral species toward the substrate support. The electron source directs electrons toward the substrate support. The first chamber may be separated from the substrate by an ion filter and the method may include directing predominately cations, rather than electrons, through the filter to the substrate. Along with the step of generating a remote plasma, the method may also includes directing predominately reactive neutral species, rather than ions and electrons, to the substrate. The apparatus or method may reduce structural charging on the substrate.

### TECHNICAL FIELD

The invention pertains to plasma processing apparatuses and methods, including atomic layer deposition.

### BACKGROUND OF THE INVENTION

The use of plasma in deposition and etch processes constitutes a well known technology and uses a wide variety of process parameters to adapt to a variety of applications. Even so, areas of improvement still exist, especially as feature sizes continually shrink in semiconductor processing, one of the common applications for plasma deposition or etch processes. In particular, high density plasma (HDP) may be used for chemical vapor deposition (CVD) but difficulty has been encountered with reliably filling high aspect ratio structures. Within the context of the present document, “high density plasma” refers to plasma having a density of at least 10¹⁰ ions per centimeters (ions/cm³) and “high aspect ratio” structures include those exhibiting an aspect ratio greater than about 3:1. Silicon dioxide dielectric material is one example of a substance for which improvement may be desired in filling high aspect ratio structures using HDP-CVD.

### SUMMARY OF THE INVENTION

In one aspect of the invention, a plasma processing apparatus includes a processing chamber having a substrate support located therein and at least two devices selected from the following three devices: a plasma generation chamber, a remote plasma generator, and an electron source. The plasma generation chamber is separated from the substrate support by an ion filter. The remote plasma generator and the electron source are each operationally associated with the substrate support.

In another aspect of the invention, a plasma processing apparatus includes a processing chamber having a substrate support located therein and at least two separate and independently controlled devices selected from the following three devices: a first plasma generator, a second plasma generator, and an electron source. The first plasma generator directs plasma-generated cations toward the substrate support. The second plasma generator directs plasma-generated reactive neutral species toward the substrate support. The electron source directs electrons toward the substrate support.

In a further aspect of the invention, a plasma processing apparatus includes a processing chamber having a temperature controlled susceptor located therein that is configured to receive a bulk semiconductor wafer. The apparatus includes the following three separate and independently controlled devices: a plasma generation chamber, a remote plasma generator, and an electron flood gun. The plasma generation chamber is separated from the susceptor by a biased grid configured, depending upon the bias, to repel cations from or accelerate cations through openings in the grid to the susceptor. The processing chamber includes shielding sufficient to segregate plasma of the plasma generation chamber from the susceptor. The remote plasma generator is configured to direct reactive neutral species, but not ions and electrons, to the susceptor. The electron flood gun is configured to direct electrons to the susceptor.

In a still further aspect of the invention, a plasma processing method includes providing a substrate on a support in a processing chamber and performing at least two separate steps selected from the following three steps: generating a first plasma in a first chamber, generating a remote second plasma, and directing electrons from a electron source to the substrate. The first chamber is separated from the substrate by an ion filter and the method includes directing predominately cations, rather than electrons, through the filter to the substrate. Along with the step of generating a remote plasma, the method also includes directing predominately reactive neutral species, rather than ions and electrons, to the substrate.

In another aspect of the invention, a plasma processing method includes providing a bulk semiconductor wafer on a temperature controlled susceptor in a processing chamber and performing three separate and independently controlled steps. The steps include generating a first plasma in a first chamber separated from the wafer by a biased grid and selecting the bias to accelerate cations, but not electrons, through openings in the grid to the wafer. The processing chamber includes shielding sufficient to segregate the first plasma from the wafer. The steps also include generating a remote second plasma and directing reactive neutral species, but not ions and electrons, to the wafer. The steps further include directing electrons from an electron flood gun to the wafer. By way of example, the method may further include reducing structural charging on the substrate compared to structural charging that otherwise occurs without the separate step of directing electrons to the wafer.

In still another aspect of the invention, a plasma processing method includes providing a substrate on a support in a processing chamber, heating the substrate while flowing deposition precursors into the processing chamber without any plasma, and chemical vapor depositing a layer comprising silicon oxide on the substrate. The method includes generating a plasma in a plasma generation chamber separated from the substrate by an ion filter and directing predominately cations, rather than electrons, through the filter to the layer. The layer is sputtered with the cations and a localized thickness of the layer is increased with a redeposited portion of the layer. By way of example, the layer may be in an opening of the substrate and the sputtering may increase layer thickness at a bottom of the opening. The method may further comprise repeating the chemical vapor depositing and the sputtering and filling the opening.

In a further aspect of the invention, a plasma processing method includes providing a substrate on a support in a processing chamber, flowing a first precursor into the processing chamber without any plasma, and chemisorbing a monolayer on the substrate using the first precursor. The method includes generating a plasma in a plasma generation chamber separated from the substrate by an ion filter and directing predominately cations, rather than electrons, through the filter to the substrate. The monolayer is modified with the cations. By way of example, modifying the monolayer may include removal of first precursor ligands. The cations may contain hydrogen ions and the first precursor ligands may contain halogen.

### BRIEF DESCRIPTION OF THE DRAWINGS

Preferred embodiments of the invention are described below with reference to the following accompanying drawings.

FIG. 1 is a schematic view of a plasma processing apparatus according to one aspect of the invention.

FIG. 2 is a schematic view of a plasma processing apparatus according to another aspect of the invention.

FIG. 3 is a partial, sectional view of a substrate in process.

FIG. 4 is a partial, sectional view of the FIG. 3 substrate at a subsequent, conventional process step.

FIG. 5 is a partial, sectional view of the FIG. 3 substrate at a subsequent process step according to one aspect of the invention.

### DETAILED DESCRIPTION OF THE PREFERRED EMBODIMENTS

Generally, those of ordinary skill recognize three types of species created in a plasma. “Reactive neutral” species refer to atoms or molecules altered by the plasma to a more reactive state, but which are not ionized and so are neutral as to charge. Reactive neutral species typically may be chemically unstable and reactive when encountering another substance. A neutral oxygen atom (O*) derived from oxygen gas (O₂) is one example of a reactive neutral species. A plasma also creates ions, generally cationic, such as oxygen cations including O⁺ and O₂⁺. The third species created in a plasma includes free electrons whose movement typically matches the frequency of the applied energy generating the plasma. For example, in a radio frequency (RF) plasma operating at 13.56 megahertz (MHz) electron motion is also at 13.56 MHz. Due to their significantly greater mass, ions and reactive neutral species do not exhibit the same type of motion as electrons.

Even though a variety of feed gases may be used to generate a plasma, the quantity of reactive neutral species, ions, and electrons generated in the plasma are inherently coupled to one another in essentially fixed ratios depending upon the processing conditions and feed gas composition. Accordingly, conventional plasma processing, whether etching, depositing, or performing another plasma treatment, merely generates a plasma containing all three species that function in combination to obtain the desired effect. While feed gases and processing conditions may be optimized, even such optimization fails to adequately resolve some difficulties, for example, in some deposition processes.

Accordingly, apparatuses and/or methods capable of decoupling the relative quantity of reactive neutral species, ions, and/or electrons, introduce additional variables that may be relied upon to further optimize plasma processing. Specifically, separately providing two or more of the three species represents a previously unrecognized opportunity for process optimization. Independent control of the two or more separately provided species may render optimization relatively straightforward once the effects of specie quantities are adequately understood.

One example of difficulties encountered in conventional processes includes HDP-CVD in high aspect ratio openings when a deposition substrate is not biased. Even so, the below described phenomena may occur in other plasma deposition or etch processes and with substrate bias. Because the prevalence of reactive neutral species and cations are coupled, obtaining a desirably high flux of reactive neutral species also results in high ionization levels that produce a high cation flux and electron flux. The negatively charged electrons tend to accumulate on the substrate. Operating with substrate bias is known to increase the energy of ions directed from the plasma to the substrate and may increase etching effects during deposition. However, even without substrate bias, observation indicates that high ionization levels produce enough structural charging to build up potentials between the plasma and substrate that result in ion acceleration toward the substrate. Sharp corners on a substrate tend to develop higher electrical potentials than corners that are more gradual. Similarly, other extreme topographical features, such as high aspect ratio openings, tend to develop strong electric fields within their structure.

Conventionally, RF bias power may be applied to a substrate that couples capacitively into the plasma region resulting in development of a significant sheath potential at the substrate surface. The sheath potential can accelerate ions toward the substrate surface and thus control ion bombardment energies. In a similar manner, the above described increased structural charging tends to attract more cations in comparison to other areas of a substrate with lower negative charge accumulation. Observation has indicated that, even without RF bias power, side wall deposition in high aspect ratio openings can be inhibited. A belief exists that the inhibited deposition results from ion acceleration toward negative charge accumulations associated with the openings in a manner that sputters away reactive neutral species deposited on the side walls. Structural charging in plasma processing can produce other uneven deposition and/or etch effects in other locations of a substrate.

Decoupling and providing independent control of reactive neutral species, ion, and electron generation can assist in resolving a structural charging problem and other problems that may be encountered in plasma processing. Specifically, decoupling and independent control can enhance structure fill capability.

In one aspect of the invention, a plasma processing apparatus includes a processing chamber having a substrate support located therein and at least two devices selected from the following three devices: a plasma generation chamber, a remote plasma generator, and an electron source. The plasma generation chamber is separated from the substrate support by an ion filter. The remote plasma generator and the electron source are each operationally associated with the substrate support. By way of example, the substrate support may be configured to receive a bulk semiconductor wafer. Also, the plasma processing apparatus may be comprised by a deposition system. Alternatively, the plasma processing apparatus may be comprised by an etch system. Those of ordinary skill will appreciate that the plasma generation chamber, remote plasma generator, and electron source may be incorporated into a variety of known plasma processing apparatuses.

In the context of this document, the term “semiconductor substrate” or “semiconductive substrate” is defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

Typically, a processing chamber of conventional apparatuses includes a plasma generation device that provides a plasma contacting a substrate positioned in the substrate support. However, one of the possible three devices in the plasma processing apparatus according to the aspects of the invention is separated from the substrate support by an ion filter. Accordingly, adding an ion filter to a conventional plasma processing chamber may provide the inventive plasma generation chamber. Similarly, a remote plasma generator may be added to a conventional plasma processing chamber to operationally associate with the substrate support. Likewise addition may occur for an electron source.

Conventional plasma processing chambers often include a temperature controlled susceptor as the substrate support. Such a susceptor may also find advantageous use in the inventive plasma processing apparatus. Further, the plasma generation chamber may generate a plasma according to any conventional technology. The plasma generation chamber may include an inductively coupled plasma generator. Electron cyclotron resonance plasma generators may also be suitable. The plasma generation chamber may be differentially pumped (separately evacuated using a separate pump) with respect to a main process chamber.

It is an advantage of the inventive plasma generation chamber that it may be configured to direct cations toward the substrate support. Providing cations to a substrate in the substrate support may occur by control of the plasma generation chamber independent of the remote plasma generator and electron source. The ion filter constitutes a device allowing or preferring cations to pass through while rejecting or restricting electrons. The ion filter may include a biased grid configured, depending upon the bias, to repel cations from or accelerate cations through openings in the grid. The grid may include a conductive mesh. Openings in the mesh can average from about 100 to about 1000 micrometers (μm) in diameter. Using micromachining techniques, the size range for openings might be reduced to as low as about 10 μm.

The plasma generation chamber may include an RF applicator and the processing chamber may include RF shielding sufficient to segregate plasma from the substrate support. Such RF shielding may exist by providing metal walls for most or all of the processing chamber and the plasma generation chamber. A suitable metal wall type of construction has been provided in conventional deposition chambers and often includes a dielectric window for viewing the plasma processing. Such chambers may be adapted to provide other aspects of the invention described herein. The conductive surfaces shield RF from being generated below the ion filter or grid and, thereby, prevent plasma generation in the processing chamber.

The remote plasma generator may be configured to direct predominately reactive neutral species, rather than ions and electrons, toward the substrate support. Independent control of the remote plasma generator thus provides reactive neutral species without coupling to the prevalence of ions or electrons. Preferably, the remote plasma generator is configured to direct no ions and electrons toward the substrate support. Known remote plasma generators are conventionally available to provide predominately reactive neutral species, rather than ions and electrons. Conventional remote plasma generators are also available that provide reactive neutral species as the only species so as not to direct ions and electrons toward a substrate support. Among the variety of remote plasma generators, those with a microwave applicator (2.45 gigahertz (GHz)) may be most suitable for the inventive plasma processing apparatuses. Microwave-generated plasma tends to exhibit higher density. Inductively coupled devices as remote plasma generators have recently become available. Even though suitable remote plasma generators are well known, the advantage of a plasma processing apparatus with a remote plasma generator as well as an electron source or plasma generation chamber with an ion filter has not been appreciated in the art.

The electron source may be configured to direct electrons toward the substrate support. Independent control of the electron source thus provides electrons without coupling to the prevalence of reactive neutral species or ions. The electron source may be an electron flood gun. Conventional electron sources and electron flood guns are suitable for the inventive plasma processing apparatuses. Even so, as indicated, combination with one or two of the other three devices has not been appreciated in the art.

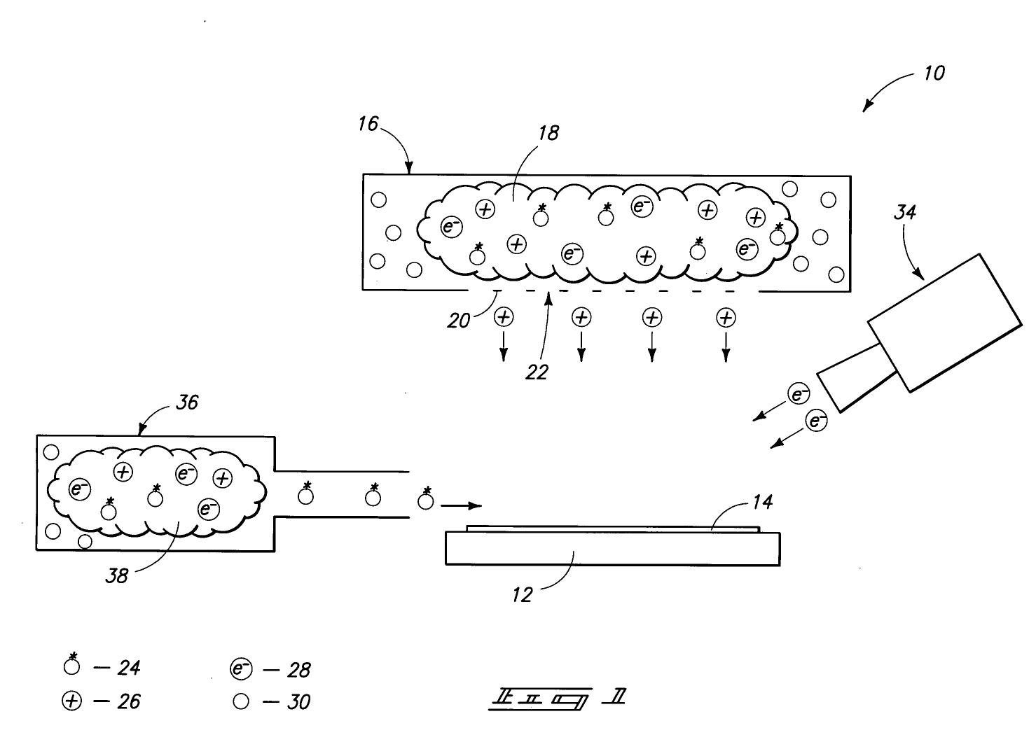

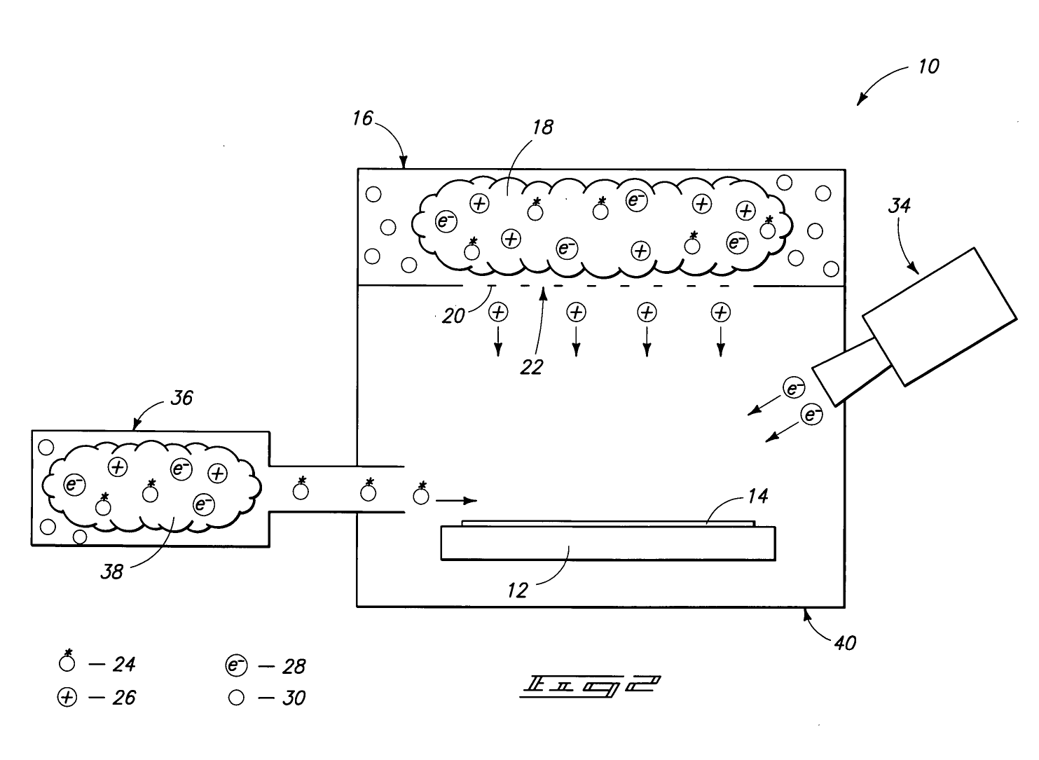

Turning to FIGS. 1 and 2 a plasma processing apparatus 10 includes a plasma generation chamber 16, a remote plasma generator 36, and an electron flood gun 34. Reactive neutral species 24, cations 26, and electrons 28 generated from such devices may be directed toward a silicon wafer 14 positioned on a susceptor 12. In chamber 16, a plasma 18 may be generated by any conventional means using feed gas 30. Plasma 18 is shown to contain reactive neutral species 24, cations 26, and electrons 28. However, mesh 20 includes openings 22 and may function as an ion filter.

A bias, V_{g}, may be applied to mesh 20 acting as a biased grid. Another bias, Vₚ, may be used to generate plasma 18. When V_{g} is less than Vₚ, mesh 20 repels electrons such that they remain within plasma 18 but accelerates cations from plasma 18 through openings 22 and directs them toward silicon wafer 14. The reverse effect occurs when V_{g} is greater than Vₚ. Vₚ is typically positive with respect to ground and varies according to known parameters depending upon the type of plasma selected. For cation acceleration, V_{g} may be negative with respect to ground and less than about 250 volts (V) in magnitude. The absolute difference between Vₚ and V_{g} may be from about 10 to about 250 V. Bias control to the grid can occur by application of DC power. Ion energy of cations accelerated through openings in the grid is equal to the ion charge times the difference between Vₚ and V_{g}. In this manner, plasma generation chamber 16 essentially functions as a wide beam ion gun. Accordingly, mesh 20 or some other material functioning as an ion filter may be sized to provide a beam of ions to cover all of wafer 14. Alternatively, a smaller ion beam might be generated and scanning motions (for example, beam rastering) initiated to cover silicon wafer 14. Many configurations of acceleration electrodes known to those of ordinary skill for use in ion guns may be acceptable for use as the ion filter of plasma generation chamber 16.

Remote plasma generator 36 is shown with plasma 38 created therein from feed gas 30 and containing reactive neutral species 24, cations 26, and electrons 28. However, in keeping with conventional remote plasma generators, only reactive neutral species 24 exit from remote plasma generator 36 directed toward silicon wafer 14. Feed gas 30 may be different or the same for remote plasma generator 36 and plasma generation chamber 16. Different feed gases may provide more opportunity for process optimization given the added variables. Electron flood gun 34 is shown generating and directing electrons 28 toward substrate 14.

Those of ordinary skill will readily appreciate the operating conditions, circuitry, controllers, etc. conventionally known that may be selected to achieve the described result of independently controlling introduction of reactive neutral species 24, cations 26, and electrons 28. Many features of the three devices generating the species are well known enough that little or no experimentation is needed. Even so, it is apparent that those of ordinary skill have not previously combined such devices, especially not for the purposes of materials processing described herein. Because the three devices of FIG. 1 are adaptable to a variety of plasma processing systems, they are shown schematically without limitation as to particular positions, numbers of units generating such species, or other conditions or parameters not relevant to the object and designs described herein.

FIG. 2 shows one possible embodiment where an existing plasma processing chamber 40 is adapted to independently control introduction of the three species by installing mesh 20 to segregate the normally unsegregated plasma 18 from silicon wafer 14. While mesh 20 functioning as an ion filter restricts introduction of electrons, shielding provided as a part of process chamber 40 prevents generation of a plasma in parts of the device outside of plasma generation chamber 16. Reactive neutral species 24 are introduced through existing unused ports of process chamber 40 from remote plasma generator 36. Similarly, electrons 28 may be introduced through other unused ports of process chamber 40 from electron flood gun 34. Multiple remote plasma generators and/or electron flood guns and the like may be situated at advantageous positions to provide adequate coverage of silicon wafer 14 or other processing substrates.

In another aspect of the invention, a plasma processing apparatus includes a processing chamber having a substrate support located therein and at least two separate and independently controlled devices selected from the following three devices: a first plasma generator, a second plasma generator, and an electron source. The first plasma generator directs plasma-generated cations toward the substrate support. The second plasma generator directs plasma-generated reactive neutral species toward the substrate support. The electron source directs electrons toward the substrate support.

By way of example, the plasma processing apparatus can include the first generator and further include a means for segregating plasma of the first generator from the substrate support. The first generator can include an RF applicator and the means for segregating may include RF shielding. The first generator can include a plasma generation chamber separated from the substrate support by an ion filter. The ion filter may include a biased grid configured, depending upon the bias, to repel cations from or accelerate cations through openings in the grid. The second generator can include a remote plasma generator. The second generator may be configured to direct no ions and electrons toward the substrate support. The electron source can include an electron flood gun.

In a further aspect of the invention, a plasma processing apparatus includes a processing chamber having a temperature controlled susceptor located therein that is configured to receive a bulk semiconductor wafer. The apparatus includes the following three separate and independently controlled devices: a plasma generation chamber, a remote plasma generator, and an electron flood gun. The plasma generation chamber is separated from the susceptor by a biased grid configured, depending upon the bias, to repel cations from or accelerate cations through openings in the grid to the susceptor. The processing chamber includes shielding sufficient to segregate plasma of the plasma generation chamber from the susceptor. The remote plasma generator is configured to direct reactive neutral species, but not ions and electrons, to the susceptor. The electron flood gun is configured to direct electrons to the susceptor.

In addition to plasma processing apparatuses, aspects of the invention also include methods of using the plasma processing apparatuses and/or plasma processing methods. In one aspect of the invention, a plasma processing method includes providing a substrate on a support in a processing chamber and performing at least two separate steps selected from the following three steps: generating a first plasma in a first chamber, generating a remote second plasma, and directing electrons from a electron source to the substrate. The first chamber is separated from the substrate by an ion filter and the method includes directing predominately cations, rather than electrons, through the filter to the substrate. Along with the step of generating a remote plasma, the method also includes directing predominately reactive neutral species, rather than ions and electrons, to the substrate.

By way of example, the at least two separate steps may be independently controlled. The first plasma may be generated using an inert gas and may be generated using exclusively inert gas. By using inert gas, neutral species that may be generated by the first plasma typically are not reactive. Thus, if they pass through the ion filter into the process chamber they do not react with other materials in the process chamber. Exemplary inert gases include noble gases and preferably consist of a noble gas. The first plasma can be an ICP. Also, directing predominately cations can include not directing electrons to the substrate. Generating the first plasma can include applying RF energy. Preferably, the processing chamber includes RF shielding sufficient to segregate the first plasma from the substrate. The ion filter can include a biased grid and the method can include selecting the bias to accelerate the cations through openings in the grid.

The remote plasma may be generated by using a microwave applicator. Further, directing predominately reactive neutral species can include not directing ions and electrons to the substrate. The remote plasma may be generated using a silicon source, an oxygen source, and an inert gas. Such feed gases may be used to deposit silicon oxide on the substrate. Silicon oxide deposition constitutes one especially significant use for the aspects of the apparatus and method inventions described herein. However, those of ordinary skill will readily appreciate that the inventions may be adapted to a variety of deposition methods and etch methods. Atomic layer deposition (ALD) is one example of a deposition method.

Using the existing knowledge of those of ordinary skill, various combinations of feed gases and source materials may be selected and introduced primarily through devices generating predominately reactive neutral species. Although, it may instead be desirable to introduce some non-inert feed gases through devices generating predominately cations. When multiple feed gases are relied upon, they may be introduced through a single device or may be introduced through separate devices. For example, multiple remote plasma generators may be provided. One may be for a silicon source and another for an oxygen source with each also including an inert carrier gas. Inputs from such remote plasma generators may be symmetrically located around a processing chamber. In the method where the silicon source and oxygen source for silicon oxide deposition pass through a remote plasma generator to provide reactive neutral species, the device directing predominately cations to the substrate may use inert gas for generation of the cations. Such cations may be accelerated through the ion filter to provide sufficient ion energy for the deposition process.

The present method may include the separate step of directing electrons to the substrate. Accordingly, the method may further include reducing structural charging on the substrate compared to structural charging that otherwise occurs without the separate step of directing electrons to the substrate. It will be appreciated that the apparatuses and methods described herein enable directing cations, but not electrons, and reactive neutral species, but not ions and electrons, to the substrate from separate devices. Given the bombardment of cations in the absence of electrons, a positive charge can accumulate on the substrate with localized high charge densities in comparison to other areas of the same substrate. Eventually, the charge accumulation may begin to repel additional cations directed to the substrate.

Ideally, plasma processing according to the aspects of the invention occurs without negative or positive charge accumulations on the substrate. Accordingly, separately directing electrons to the substrate can, in general, prevent substrate charging and, more specifically, prevent localized charge accumulations associated with particular structures. In this manner, layers of uniform thickness can be deposited.

When using conventional methods and apparatuses, structural charging may cause thickness variations in a deposited layer. By decoupling the flux of reactive neutral species and cations and providing structural charge control, it is conceivable that aspects of the invention might be configured also to deposit layers with intentional variation in thickness. For example, bottom-up fill of openings in a substrate might be achieved.

In a still further aspect of the invention, a plasma processing method includes providing a bulk semiconductor wafer on a temperature controlled susceptor in a processing chamber and performing three separate and independently controlled steps. The steps include generating a first plasma in a first chamber separated from the wafer by a biased grid and selecting the bias to accelerate cations, but not electrons, through openings in the grid to the wafer. The processing chamber includes shielding sufficient to segregate the first plasma from the wafer. The steps also include generating a remote second plasma and directing reactive neutral species, but not ions and electrons, to the wafer. The steps further include directing electrons from an electron flood gun to the wafer. By way of example, the method may further include reducing structural charging on the substrate compared to structural charging that otherwise occurs without the separate step of directing electrons to the wafer.

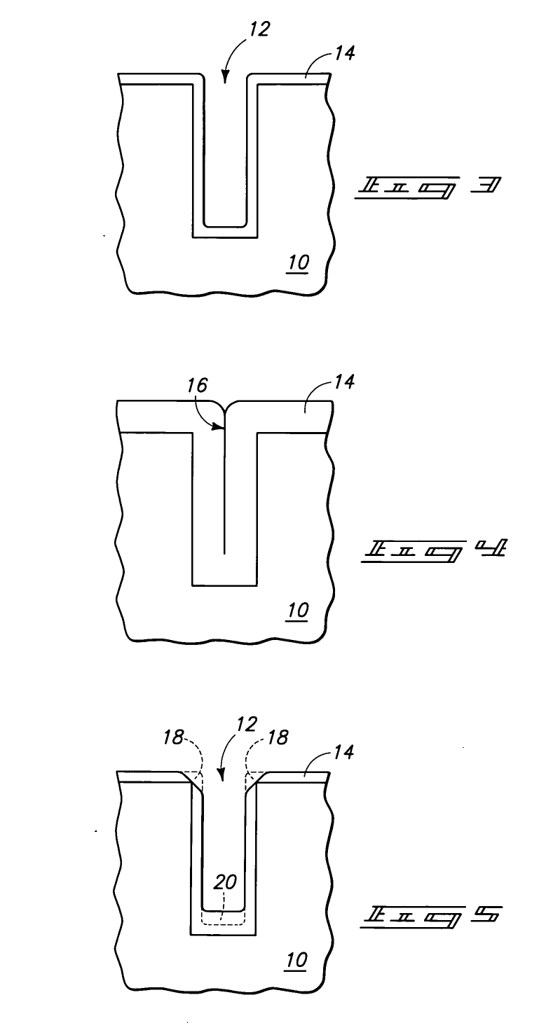

In another aspect of the invention, the plasma processing methods and apparatuses described herein may be applied to a deposition process by providing a substrate on a support in a processing chamber and heating the substrate while flowing deposition precursors into the processing chamber without any plasma. The method includes chemical vapor depositing a layer containing silicon oxide on the substrate. A silicon oxide layer resulting from thermal CVD, such as described, typically exhibits good step coverage. Accordingly, thermal CVD layer thickness on the side walls of high aspect ratio openings may be very close to layer thickness on horizontal surfaces of the material into which the openings are formed. FIG. 3 shows a substrate 10 with an opening 12 formed therein and a layer 14 of uniform thickness formed on substrate 10, including within opening 12. However, as deposition proceeds in FIG. 4 to increase layer 14 thickness and fill opening 12, a seam 16 forms where layers on opposing sidewalls meet. Seam 16 degrades the quality of the fill material in opening 12.

The present aspect of the invention includes generating a plasma in a plasma generation chamber separated from the substrate by an ion filter and directing predominately cations, rather than electrons, through the filter to the silicon oxide layer deposited by thermal CVD. The method includes sputtering the layer with the cations and increasing a localized thickness of the layer with a redeposited portion of the layer. By way of example, the layer may be in an opening of the substrate and the sputtering may increase layer thickness at a bottom of the opening. The method can further include repeating the chemical vapor depositing and the sputtering and filling the opening. One or more additional cycles may be suitable depending upon dimensions of the layer and the opening and the extent of sputtering.

Sputtering the silicon oxide layer may occur after stopping the CVD. As an alternative, it may be possible to sputter with the cations during CVD, but the cations might detrimentally affect the precursor species. Thermal CVD process conditions can include any known to those of ordinary skill. The deposition precursors can include SiH₄ along with O₂ and/or O₃.

As shown in FIG. 5, corners 18 of layer 14 are sputtered and redeposited as fill 20, increasing layer 14 thickness at the bottom of opening 12. Without limitation to any particular theory, it is believed that the cations mainly sputter the layer deposited on corners of the substrate and the sputtered material from the deposited layer redeposits in the opening. Sputtering rate is known to be a function of the incident angle of the cations with maximum sputtering generally occurring for surfaces at an incident angle between 45° and 85°. Accordingly, little sputtering occurs of the layer on the side walls. If sputtered material from the deposited layer redeposits instead on the side walls, forming protrusions, then such protrusions will likely be removed during subsequent sputtering given the incident angle of cations upon such protrusions. Thus, a high aspect ratio opening may be efficiently filled while reducing or eliminating a seam in the fill material.

Also, directing predominately cations, rather than electrons, to the silicon oxide layer reduces the problem of structure charging that causes non-conformal deposition in HDP-CVD. Not directing any electrons to the silicon oxide layer further reduces such problem. As discussed above, the coupled generation of plasma species in HDP-CVD can create a problem with side wall layer thickness. When attempting to fill the openings, HDP-CVD can thus create voids in the openings. Unfortunately, any sputtering that may occur in HDP-CVD is not controlled independent of deposition rate, determined primarily by generation of reactive neutral species, or independent of structural charging due to the coupling of plasma-generated species. Accordingly, the aspects of the invention uniquely resolve problems in the art.

In a further aspect of the invention, the plasma processing methods and apparatuses described herein may be applied to an ALD process by providing a substrate on a support in a processing chamber and flowing a first precursor into the processing chamber without any plasma. The method includes chemisorbing a monolayer on the substrate using the first precursor. A plasma is generated in a plasma generation chamber separated from the substrate by an ion filter and predominately cations, rather than electrons, are directed through the filter to the substrate. The monolayer is modified with the cations.

By way of example, modifying the monolayer may include removal of first precursor ligands. The cations may contain hydrogen ions and the first precursor ligands may contain halogen. TiCl₄ represents one common example of an ALD precursor with a halogen ligand. The ion filter can include a biased grid and the method can include selecting the bias to accelerate cations through openings in the grid during modification of the monolayer and selecting the bias to repel cations from the openings during chemisorption of the monolayer. As may be appreciated from the description above of ion acceleration with a biased grid, the bias selected to repel cations from the openings may accelerate electrons through the grid. However, a relatively low potential between V_{g} and Vₚ, e.g. less than about 15 to 20 volts, may be selected such that the energy of electrons accelerated through the grid is very small, producing only negligible detrimental effects upon the monolayer and no sputtering given the very small mass of electrons compared to cations.

In this manner, the plasma can be maintained at a steady state throughout an ALD process and cations kept from the deposition substrate when desirable, for example, during chemisorption. Maintaining the plasma is preferred over the alternative of pulsing the plasma on and off throughout ALD. However, conventional methods do not provide decoupling of plasma species and selective application thereof in desired ALD steps as in the aspects of the invention herein. A variety of ALD applications for the aspects of the invention will be appreciated by those of ordinary skill in light of conventional modulated ALD, such as described in U.S. Pat. No. 6,416,822 issued to Chiang et al. However, the prior art does not appreciate the decoupling of plasma species described herein and its usefulness.

ALD involves formation of successive atomic layers on a substrate. Such layers may comprise an epitaxial, polycrystalline, amorphous, etc. material. ALD may also be referred to as atomic layer epitaxy, atomic layer processing, etc. Described in summary, ALD includes exposing an initial substrate to a first chemical precursor to accomplish chemisorption of the precursor onto the substrate. Theoretically, the chemisorption forms a monolayer that is uniformly one atom or molecule thick on the entire exposed initial substrate. In other words, a saturated monolayer. Practically, as further described below, chemisorption might not occur on all portions of the substrate. Nevertheless, such an imperfect monolayer is still a monolayer in the context of this document. In many applications, merely a substantially saturated monolayer may be suitable. A substantially saturated monolayer is one that will still yield a deposited layer exhibiting the quality and/or properties desired for such layer.

The first precursor is purged from over the substrate and a second chemical precursor is provided to react with the first monolayer of the first precursor. The second precursor is then purged and the steps are repeated with exposure of the deposited monolayer to the first precursor. In some cases, the two monolayers may be of the same precursor. As an option, the second precursor can react with the first precursor, but not chemisorb additional material thereto. As but one example, the second precursor can remove some portion of the chemisorbed first precursor, altering such monolayer without forming another monolayer thereon. Also, a third precursor or more may be successively chemisorbed (or reacted) and purged just as described for the first and second precursors.

In the context of the present document, “reacting” or “reaction” refers to a change or transformation in which a substance decomposes, combines with other substances, or interchanges constituents with other substances. Thus, it will be appreciated that “chemisorbing” or “chemisorption” is a specific type of reacting or reaction that refers to taking up and chemically binding (a substance) onto the surface of another substance.

Purging may involve a variety of techniques including, but not limited to, contacting the substrate and/or monolayer with a carrier gas and/or lowering pressure to below the deposition pressure to reduce the concentration of a precursor contacting the substrate and/or chemisorbed precursor. Examples of carrier gases include N₂, Ar, He, etc. Purging may instead include contacting the substrate and/or monolayer with any substance that allows chemisorption byproducts to desorb and reduces the concentration of a contacting precursor preparatory to introducing another precursor. The contacting precursor may be reduced to some suitable concentration or partial pressure known to those skilled in the art as suitable based upon the specifications for the product of a particular deposition process.

ALD is often described as a self-limiting process, in that a finite number of sites exist on a substrate to which the first precursor may form chemical bonds. The second precursor might only bond to the first precursor and thus may also be self-limiting. Once all of the finite number of sites on a substrate are bonded with a first precursor, the first precursor will often not bond to other of the first precursor already bonded with the substrate. However, process conditions can be varied in ALD to promote such bonding and render ALD not self-limiting. Accordingly, ALD may also encompass a precursor forming other than one monolayer at a time by stacking of a precursor, forming a layer more than one atom or molecule thick. The various aspects of the present invention described herein are applicable to any circumstance where ALD may be desired. A few examples of materials that may be deposited by ALD include metals, metal oxides, metal nitrides, and others.

Typically, traditional ALD occurs within an often-used range of temperature and pressure and according to established purging criteria to achieve the desired formation of an overall ALD layer one monolayer at a time. Even so, ALD conditions can vary greatly depending on the particular precursors, layer composition, deposition equipment, and other factors according to criteria known by those skilled in the art. Maintaining the traditional conditions of temperature, pressure, and purging minimizes unwanted reactions that may impact monolayer formation and quality of the resulting overall ALD layer. Accordingly, operating outside the traditional temperature and pressure ranges may risk formation of defective monolayers.

The general technology of chemical vapor deposition (CVD) includes a variety of more specific processes, including, but not limited to, plasma enhanced CVD and others. CVD is commonly used to form non-selectively a complete, deposited material on a substrate. One characteristic of CVD is the simultaneous presence of multiple precursors in the deposition chamber that react to form the deposited material. Such condition is contrasted with the purging criteria for traditional ALD wherein a substrate is contacted with a single deposition precursor that chemisorbs to a substrate or reacts with a previously deposited precursor. An ALD process regime may provide a simultaneously contacted plurality of precursors of a type or under conditions such that ALD chemisorption, rather than CVD reaction occurs. Instead of reacting together, the plurality of precursors may chemisorb to a substrate or previously deposited precursor, providing a surface onto which subsequent precursors may next chemisorb or react to form a complete layer of desired material.

Under most CVD conditions, deposition occurs largely independent of the composition or surface properties of an underlying substrate. By contrast, chemisorption rate in ALD might be influenced by the composition, crystalline structure, and other properties of a substrate or chemisorbed precursor. Other process conditions, for example, pressure and temperature, may also influence chemisorption rate. In comparison to the predominantly thermally driven CVD, ALD is predominantly chemically driven. Accordingly, ALD is often conducted at much lower temperatures than CVD.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1. A plasma processing apparatus comprising:
a processing chamber having a substrate support located therein; and
at least two separate devices selected from the following three devices:
a) a plasma generation chamber separated from the substrate support by an ion filter;
b) a remote plasma generator operationally associated with the substrate support; and
c) an electron source operationally associated with the substrate support.

2. The apparatus of claim 1 wherein the substrate support comprises a temperature controlled susceptor.

3. The apparatus of claim 1 wherein the substrate support is configured to receive a bulk semiconductor wafer.

4. The apparatus of claim 1 wherein the at least two separate devices are independently controlled.

5. The apparatus of claim 1 wherein the plasma generation chamber is configured to direct cations toward the substrate support.

6. The apparatus of claim 1 wherein the plasma generation chamber comprises an ICP generator.

7. The apparatus of claim 1 wherein the plasma generation chamber comprises an RF applicator and the processing chamber comprises RF shielding sufficient to segregate plasma from the substrate support.

8. The apparatus of claim 1 wherein the ion filter comprises a biased grid configured, depending upon the bias, to repel cations from or accelerate cations through openings in the grid.

9. The apparatus of claim 8 wherein the grid comprises a conductive mesh and the openings average from about 100 to about 1000 μm in diameter.

10. The apparatus of claim 1 wherein the remote plasma generator is configured to direct predominately reactive neutral species, rather than ions and electrons, toward the substrate support.

11. The apparatus of claim 1 wherein the remote plasma generator is configured to direct no ions and electrons toward the substrate support.

12. The apparatus of claim 1 wherein the remote plasma generator comprises a microwave applicator.

13. The apparatus of claim 1 wherein the electron source is configured to direct electrons toward the substrate support.

14. The apparatus of claim 1 wherein the electron source comprises an electron flood gun.

15. The apparatus of claim 1 wherein the plasma processing apparatus is comprised by a deposition system.

16. The apparatus of claim 1 wherein the plasma processing apparatus is comprised by an etch system.

17. A plasma processing apparatus comprising:
a processing chamber having a substrate support located therein; and
at least two separate and independently controlled devices selected from the following three devices:
a) a first plasma generator that directs plasma-generated cations toward the substrate support;
b) a second plasma generator that directs plasma-generated reactive neutral species toward the substrate support; and
c) an electron source that directs electrons toward the substrate support.

18. The apparatus of claim 17 wherein the substrate support is configured to receive a bulk semiconductor wafer.

19. The apparatus of claim 17 comprising the first generator and further comprising a means for segregating plasma of the first generator from the substrate support.

20. The apparatus of claim 19 wherein the first generator comprises an RF applicator and the means for segregating comprises RF shielding.

21. The apparatus of claim 17 wherein the first generator comprises a plasma generation chamber separated from the substrate support by an ion filter.

22. The apparatus of claim 21 wherein the ion filter comprises a biased grid configured, depending upon the bias, to repel cations from or accelerate cations through openings in the grid.

23. The apparatus of claim 17 wherein the second generator comprises a remote plasma generator.

24. The apparatus of claim 17 wherein the second generator is configured to direct no ions and electrons toward the substrate support.

25. The apparatus of claim 17 wherein the electron source comprises an electron flood gun.

26. A plasma processing apparatus comprising:
a processing chamber having a temperature controlled susceptor located therein that is configured to receive a bulk semiconductor wafer; and
the following three separate and independently controlled devices:
a) a plasma generation chamber separated from the susceptor by a biased grid configured, depending upon the bias, to repel cations from or accelerate cations through openings in the grid to the susceptor, the processing chamber including shielding sufficient to segregate plasma of the plasma generation chamber from the susceptor;
b) a remote plasma generator configured to direct reactive neutral species, but no ions and electrons, to the susceptor; and
c) an electron flood gun configured to direct electrons to the susceptor.

27. The apparatus of claim 26 wherein the plasma generation chamber comprises an ICP generator.

28. The apparatus of claim 26 wherein the plasma generation chamber comprises an RF applicator and the shielding comprises RF shielding.

29. The apparatus of claim 26 wherein the grid comprises a conductive mesh and the openings average from about 100 to about 1000 μm in diameter.

30. The apparatus of claim 26 wherein the remote plasma generator comprises a microwave applicator.

31. The apparatus of claim 26 wherein the plasma processing apparatus is comprised by a deposition system.

32. The apparatus of claim 26 wherein the plasma processing apparatus is comprised by an etch system.

33-87. (canceled)
